(19) United States
(12) Patent Application Publication
(10) Pub. No.: US 2007/0236895 A1
(43) Pub. Date: Oct. 11, 2007

(54) Via resistor structure and method for trimming resistance value

(76) Inventors: Gerald Keith Bartley, Rochester, MN (US); Richard Boyd Ericson, Rochester, MN (US); Mark Kenneth Hoffmeyer, Rochester, MN (US); Wesley David Martin, Elgin, MN (US); Benjamin William Mashak, Rochester, MN (US); Trevor Joseph Timpane, Rochester, MN (US); Ay Vang, Vadnais Heights, MN (US)

Correspondence Address: IBM CORPORATION;ROCHESTER IP LAW DEPT 917, 3605 HIGHWAY 52 N, ROCHESTER, MN, 55901-7829, US

(21) Appl. No.: 11/393,140

(22) Filed: Mar. 30, 2006

(51) Int. Cl. H05K 1/14

(52) U.S. Cl. 361/737

(57) ABSTRACT

A via resistor structure and method are provided for implementing a resistor and for trimming a resistance value of the resistor. A resistive material selectively is deposited adjacent to a pad connecting to a via where a resistor is to be defined. A trimmed path is formed in the resistive material for selectively changing the resistance value of the resistor.

### FIELD OF THE INVENTION

The present invention relates generally to the data processing field, and more particularly, relates to a method and via resistor structure for implementing a resistor and for trimming a resistance value of the resistor.

### DESCRIPTION OF THE RELATED ART

With the advent of generally standard signaling schemes popular with processor-to-processor structures, such as, Front-side-busses, memory interfaces, and the like, the application of resistors as pull-ups, bias networks, series damping networks, and the like, has become very popular. Physical standards such as Gunning Transistor Logic (GTL) require resistors as part of their structure. These resistors have been growing in numbers on a typical electronic part for years, and with wider and more prevalent high speed busses, are increasing in numbers drastically.

Approaches being employed today range from smaller devices, to resistor packs, to embedding resistors on ASICS, to placing expensive resistive layers in the card stackup, to other approaches such as described in U.S. Pat. No. 6,404,643.

U.S. Pat. No. 6,404,643 shows a complicated set of steps to place a component within a cavity of a board, and overmold the component in such a way to make the component an integral part of the card/board structure. The disclosed arrangement is not very space efficient, and not likely to be high yielding given the process steps described.

U.S. Pat. No. 5,990,421 discloses a printed circuit board having a layer of electrically resistive material that can provide a pull-up/pull-down resistor for the printed circuit board. The printed circuit board includes a substrate which has a conductive plane located on the top surface of the board. The conductive plane is typically dedicated to electrical power. The board also has a via that is connected to an internal signal line. The resistive material is applied to the top surface to connect the conductive plane to the via and the signal line. The resistive material can be applied with a screening process, which simplifies the assembly process of the resistor. Additionally, the resistive material is relatively small and located adjacent to the via so that the resistor does not occupy valuable board space. The resistor is always present and a series damping resistor is not enabled, and there is no adjustment capability for the pull-up or pull-down resistor. The top plane being ground or power, the resistor defined by a circular pad on the top of the card is connected between the via and the power plane structure, which is required to be on the outside of the card.

The above-described patents do not address split terminations, series terminations or the ability to adjust a resistor value from negligible to several orders of magnitude larger than its un-trimmed value.

In order to save space, for example, for a given number of resistors that may be required, a method of combining the resistor with a structure, which already exists on the card, is needed. A method to adjust the value of the resistor also is needed to trim the resistor to a desired value that allows for significant variation of the resistance value without adding significant inductance or capacitance to the via. Being able to define the presence or absence of a resistor or a value of the resistor in a net post design, for example, a damping resistor in a net, would be very beneficial in adjusting memory net performance for the wide range of memory driver and receiver behaviors.

### SUMMARY OF THE INVENTION

Principal objects of the present invention are to provide a method and a via resistor structure for implementing a resistor and for trimming a resistance value of such resistor. Other important aspects of the present invention are to provide such method and structure substantially without negative effect and that overcome many of the disadvantages of prior art arrangements.

In brief, a via resistor structure and method are provided for implementing a resistor and for trimming a resistance value of the resistor. A resistive material selectively is deposited adjacent to a pad connecting to a via where a resistor is to be defined. A trimmed path is formed in the resistive material for selectively changing the resistance value of the resistor.

In accordance with features of the invention, the resistive material is implemented with a selected one of an e-coat material being loaded with at least one of a selected metal and a particulate, a plated graphite, and a polymer thick film.

In accordance with features of the invention, laser cutting forms the trimmed path in the resistive material, such as a spiral-trimmed path. A longer cut increases the resistance value of the resistor.

In accordance with features of the invention, the via resistor structure enables series damping resistors, pull-up and pull-down resistors, and split terminations.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is an isometric view not to scale illustrating an exemplary via resistor structure and method for implementing a resistor and for trimming a resistance value of the resistor in accordance with the preferred embodiment; and

FIGS. 2, 3, and 4 are top plan views illustrating alternative exemplary resistors including alternative trimmed resistive paths for implementing for trimming a resistance value in accordance with the preferred embodiment.

### DETAILED DESCRIPTION OF THE PREFERRED EMBODIMENTS

In accordance with features of the invention, a space saving arrangement for a given number of resistors is provided by combining a resistor with a via structure, which already exists on a printed circuit card. A method to adjust the value of the resistor also is provided to trim the resistor to a desired value and that allows for significant variation of the resistance value without adding significant inductance or capacitance to the via. The method enables defining the presence or absence of a resistor or a value of the resistor in a net post design. For example, a damping resistor in a net advantageously is provided by the method of the invention that is very beneficial in adjusting memory net performance for the wide range of memory driver and receiver behaviors.

In accordance with features of the invention, a tuneable via resistor structure is provided utilizing a spiral trimming process, which can be manufactured in an efficient plating process and invoked for pull-up and pull-down resistors, split terminations, and series damping resistors. This resistor can be selectively present or absent, or can be placed in a blanket, for example, on selected via caps or all via caps, and trimmed to a needed value.

In accordance with features of the invention, by utilizing a via and a pad connecting to the via, to construct the resistor, a smaller, more dense, more versatile, and more accessible resistor structure advantageously is provided relative to current approaches including resistive layer techniques. This accessibility allows for tuning or changing of the resistance value post raw-card manufacturing, providing an option for in situ tuning of the resistance value, such as for tuned net situations.

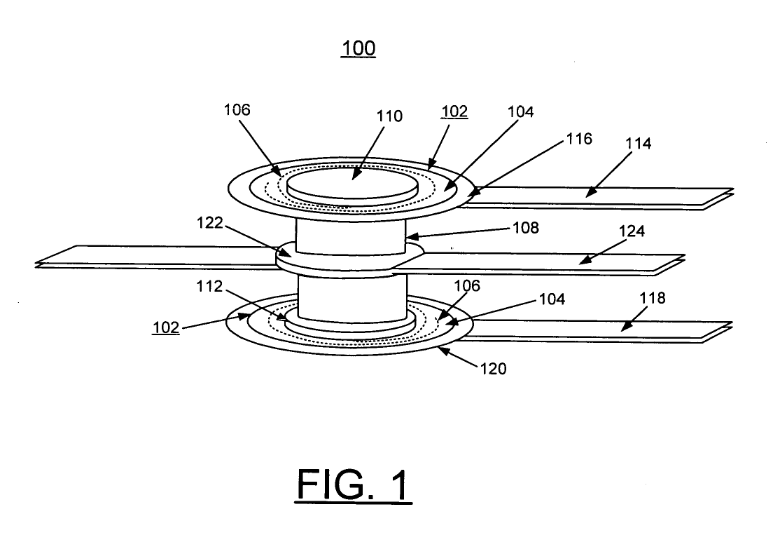

Having reference now to the drawings, in FIG. 1, there is shown an exemplary via resistor structure generally designated by the reference character 100 for implementing a resistor designated by the reference character 102 and for trimming a resistance value of the resistor 102 in accordance with the preferred embodiment.

Via resistor structure 100 includes a resistive material generally designated by the reference character 104. A spiral trimmed path generally designated by the reference character 106 is formed in the resistive material 104 for tuning or changing of the resistance value of the resistor 102 defined by resistive material 104. It should be understood that the present invention is not limited to such spiral-trimmed path 106; various other path configurations can be used.

The resistive material 104 includes for example, an e-coat material, such as including an epoxy material, a urethane material or other adhesive material, loaded with a selected one of various metals, particulates, or the like to tailor a specific resistivity characteristic. Other exemplary materials that could be used for the resistive material 104 include, for example, plated graphite and various screened polymer thick films.

In accordance with features of the invention, a methodology to be used includes starting with a base line via resistor structure with no trim cut and measure the resistance, inductance, and capacitance (R/L/C) properties of the via resistor structure 100 followed by a long spiral cut 106 and another measurement of the resulting R/L/C properties of the via resistor structure 100. A significant desired effect that is achieved with the via resistor structure 100 of the invention is that a selected adjustment of the resistance value is enabled, that can include a generally large change in the resistance value with little change in capacitance and inductance, using the trim cut in the deposited resistive material, such as the spiral trimmed path 106 as shown in FIG. 1 defining the via resistor structure 100.

Via resistor structure 100 includes an exemplary elongated, electrically conductive via generally designated by the reference character 108. Electrically conductive via 108 includes an upper electrically connected conductive capture pad 110 and a lower electrically connected conductive capture pad 112. These conductive capture pads 110, 112 may or may not have a hole in the center of them depending on a particular technology medium in which this device is implemented within. An upper signal trace 114 is electrically connected to the upper resistor 102 including an annular ring serving as a mating portion 116 surrounding the resistive material 104 that defines upper resistor 102. A lower signal trace 118 similarly includes a similar annular ring serving as a mating portion 120 electrically connected to the lower resistor 102. As shown in FIG. 1, via 108 includes an interior conductive capture pad 122 electrically connected to a predefined signal trace 124. As shown in FIG. 1, via resistor structure 100 provides a split-termination connection with the upper and lower resistors 102.

Via resistor structure 100 is shown in simplified form sufficient for understanding the present invention. For example, a printed circuit board (not shown) formed by an electrically insulative member typically contains a predefined pattern of a plurality of often closely spaced vias 108.

Using an available modeling tool, via structures have been constructed and solved to determine the effect of spiral cutting on these via resistors. The resistive material 104 selected in this case was E-Coat having 10000 Siemens/Meter.

The following Table 1 shows the results of the simulations:

TABLE 1

| | Capacitance | DC resistance | AC inductance |
|---|---|---|---|
| No cut | 5.2e−14 | 0.22 Ohms | 1.67 nH |
| Short cut: | 5.2e−14 | 3.97 Ohms | 1.69 nH |
| Long cut: | 5.21e−14 | 73.2 Ohms | 2.18 nH |

Accounting for a power or ground plane as the first layer below the spiral cut resistor 102 would reduce the inductance impact, while not affecting the range of resistor trim capability. Further the range of trimming advantageously is enhanced with providing more spirals within the trimmed path 106.

FIG. 1 provides one example of via resistor structure 100. Different materials advantageously are utilized for resistive material 104. Resistive material 104 also can include tailoring of plateable materials to achieve different ranges of resistor capability, for example, to maintain a useful range of series damping resistors 102 with a trimable range of 25:1 or perhaps larger. For example, the resistor 102 defined by resistive material 104 and without a trimmed path 104 or an untrimmed resistor could have a resistance value of about a mille-Ohm, while having the ability to create about a 10 ohm damping resistor 102 defined with a particular trimmed path 106. For example, resistors 102 can be adjusted or trimmed to allow for compensation of differences between various memory devices I/O driver performance, or to allow for the adjustment of memory net performance during the prototype phase.

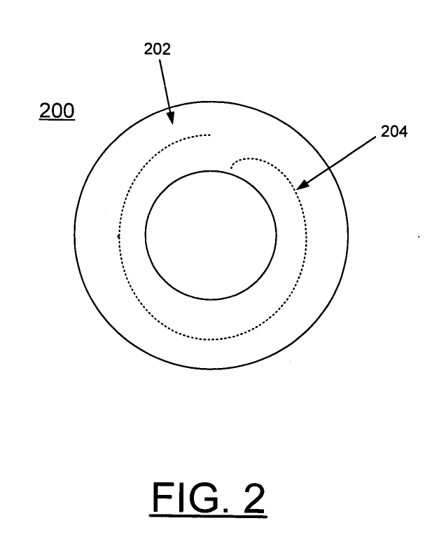

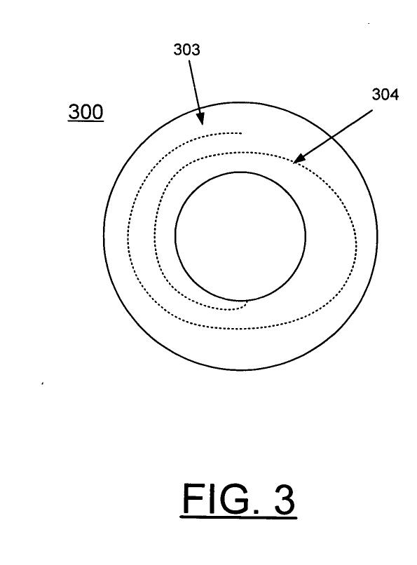

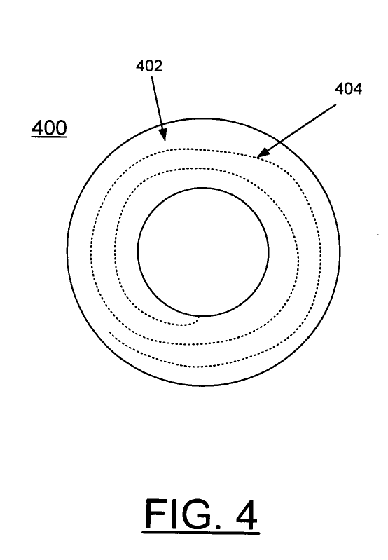

FIGS. 2, 3, and 4 respectively illustrate alternative exemplary resistors generally designated by the respective reference character 200, 300, and 400. Each of the exemplary resistors 200, 300, and 400 include a deposited resistive material 202, 302, and 402.

Resistor 200 includes a spiral trimmed resistive path 204 for implementing for trimming a resistance value in accordance with the preferred embodiment. Using the test structure modeling tool for resistor 200 with the first trim path 204, a three-dimensional resistive path analysis yielded an effective resistance of about 3.5 Ohms.

Resistor 300 includes a spiral trimmed resistive path 304 having a greater length for implementing an increased resistance value for the resistor 300 as compared to resistor 200 in accordance with the preferred embodiment.

Resistor 400 includes a spiral trimmed resistive path 404 for trimming a resistance value in accordance with the preferred embodiment. For example, resistor 400 with the substantially longer trim path 404, has an effective resistance of about 73 Ohms.

In the preferred implementation of the invention, laser cutting is used for forming the trimmed resistive path. Etching could work to some degree to increase the resistance value of a resistor; however, etching would likely be difficult to align and control, and generally would not lend itself to the level of tolerance possible with the preferred laser cutting to form the trimmed path in the deposited resistive material. Other approaches such as electron-beam, plasma etch, water-jet, abrasive etching, and the like could be used to some level of tolerance and control.

While the present invention has been described with reference to the details of the embodiments of the invention shown in the drawing, these details are not intended to limit the scope of the invention as claimed in the appended claims.

What is claimed is:

1. A method for implementing a resistor and trimming a resistance value of the resistor comprising the steps of:
selectively depositing a resistive material adjacent to a pad connecting to a via where a resistor is to be defined; and
forming a trimmed path in said deposited resistive material for selectively adjusting a resistance value of the resistor.

2. A method as recited in claim 1 wherein selectively depositing a resistive material includes the step of implementing said resistive material with a selected one of an e-coat material being loaded with at least one of a selected metal and a particulate, a plated graphite, and a polymer thick film.

3. A method as recited in claim 1 wherein selectively depositing a resistive material includes the step of selectively depositing said resistive material surrounding said pad connecting to said via.

4. A method as recited in claim 1 wherein forming a trimmed path in the resistive material includes the step of laser cutting said trimmed path in said deposited resistive material.

5. A method as recited in claim 1 wherein forming a trimmed path in the resistive material includes the step of forming said trimmed path in said deposited resistive material with a selected length, and increasing said trimmed path length to increase said resistance value of the resistor.

6. A method as recited in claim 1 wherein said deposited resistive material includes a generally circular configuration and wherein forming a trimmed path in the resistive material includes the step of laser cutting a spiral trimmed path in said deposited resistive material.

7. A method as recited in claim 6 includes increasing said trimmed path length of said spiral trimmed path in said deposited resistive material to increase said resistance value of the resistor.

8. A method as recited in claim 1 wherein said resistor enables each of a series damping resistor, a pull-up resistor, a pull-down resistor, and split termination resistors.

9. A via resistor structure including an electrically conductive via, and a pad electrically connected to said electrically conductive via; a resistor of said via resistor structure comprising:
a resistive material disposed adjacent to said pad; and
a trimmed path selectively formed in said resistive material for selectively providing a resistance value of the resistor.

10. A via resistor structure as recited in claim 9 wherein said resistive material includes a selected one of an e-coat material being loaded with at least one of a selected metal and a particulate; a plated graphite; and a polymer thick film.

11. A via resistor structure as recited in claim 9 wherein said resistive material includes a generally circular configuration; and wherein said resistive material surrounds said pad.

12. A via resistor structure as, recited in claim 9 wherein said trimmed path selectively formed in said resistive material includes a spiral trimmed path.

13. A via resistor structure as recited in claim 9 wherein said trimmed path selectively formed in said resistive material includes a selected length, and said path length being increased to provide a higher resistance value of the resistor.

14. A via resistor structure as recited in claim 9 wherein said trimmed path selectively formed in said resistive material includes a laser cut path.

15. A via resistor structure as recited in claim 9 wherein the resistor defines each of a selected one of a series damping resistor, a pull-up resistor, a pull-down resistor, and split termination resistors.
